(19) United States
(12) Patent Application Publication
(10) Pub. No.: US 2021/0043417 A1
(43) Pub. Date: Feb. 11, 2021

(54) INSPECTION METHOD AND INSPECTION APPARATUS

(71) Applicant: Kioxia Corporation, Minato-ku (JP)

(72) Inventor: Osamu NAGANO, Nagoya (JP)

(73) Assignee: Kioxia Corporation, Minato-ku (JP)

(21) Appl. No.: 16/803,213

(22) Filed: Feb. 27, 2020

(30) Foreign Application Priority Data
Aug. 9, 2019 (JP) 2019-147525

(51) Int. Cl. H01J 37/28; H01J 37/02

(52) U.S. Cl. CPC H01J 37/28; H01J 2237/2594; H01J 37/026

(57) ABSTRACT

An inspection method of an embodiment includes: positively charging a substrate on which a pattern is formed by irradiating the substrate with a first electron beam; generating a secondary electron on a surface of the substrate by irradiating the substrate with a second electron beam; detecting the generated secondary electron; and inspecting the pattern based on the detected secondary electron, in which when the substrate is irradiated with the first electron beam, the first electron beam is made incident on the substrate at an incident angle different from an incident angle of the second electron beam with respect to the substrate, while positions of an emission source of the first electron beam and the substrate are being moved relatively.

### CROSS-REFERENCE TO RELATED APPLICATIONS

This application is based upon and claims the benefit of priority from Japanese Patent Application No. 2019-147525, filed on Aug. 9, 2019; the entire contents of which are incorporated herein by reference.

### FIELD

Embodiments described herein relate generally to an inspection method and an inspection apparatus.

### BACKGROUND

A voltage contrast (VC) inspection using a potential contrast may be performed to inspect a pattern formed on a substrate. In the VC inspection, the pattern is inspected based on the secondary electrons generated by irradiating the surface of the positively charged substrate with an electron beam. As the number of stacked layers in a semiconductor device increases, it takes time to positively charge the substrate.

### BRIEF DESCRIPTION OF THE DRAWINGS

FIG. 1 is a schematic diagram illustrating a configuration example of an inspection apparatus according to a first embodiment;

FIGS. 2A and 2B are schematic diagrams illustrating a state of a pre-charging process in the inspection apparatus according to the first embodiment;

FIGS. 3A to 3C are schematic diagrams illustrating a state of the pre-charging process in the inspection apparatus according to the first embodiment;

FIGS. 4A to 4C are schematic diagrams illustrating a pattern of a wafer and a state of a VC inspection for the pattern according to the first embodiment;

FIG. 5 is a flowchart illustrating one example of a procedure of a VC inspection method according to the first embodiment;

FIG. 6 is a schematic diagram illustrating a configuration example of an inspection apparatus according to a second embodiment;

FIGS. 7A to 7D are schematic diagrams illustrating a state of a VC inspection in the inspection apparatus according to the second embodiment;

FIG. 8 is a flowchart illustrating one example of a procedure of a VC inspection method by the inspection apparatus according to the second embodiment; and

FIG. 9 is a flowchart illustrating one example of the procedure of the VC inspection method by the inspection apparatus according to the second embodiment.

### DETAILED DESCRIPTION

An inspection method of an embodiment includes: positively charging a substrate on which a pattern is formed by irradiating the substrate with a first electron beam; generating a secondary electron on a surface of the substrate by irradiating the substrate with a second electron beam; detecting the generated secondary electron; and inspecting the pattern based on the detected secondary electron, in which when the substrate is irradiated with the first electron beam, the first electron beam is made incident on the substrate at an incident angle different from an incident angle of the second electron beam with respect to the substrate, while positions of an emission source of the first electron beam and the substrate are being moved relatively.

Hereinafter, the present invention will be described in detail with reference to the drawings. The present invention is not limited by the following embodiments. Also, constituent elements in the following embodiments include those that can be easily assumed by those skilled in the art or that are substantially the same.

### First Embodiment

Hereinafter, a first embodiment will be described in detail with reference to the drawings.

(Configuration Example of Inspection Apparatus)

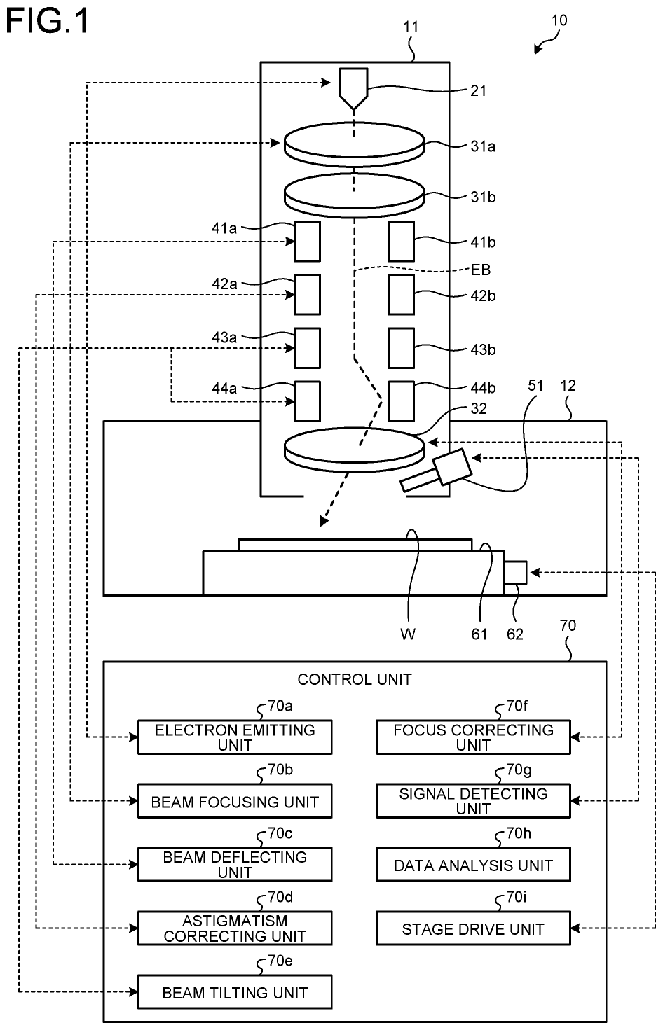

FIG. 1 is a schematic diagram illustrating a configuration example of an inspection apparatus 10 according to the first embodiment. As illustrated in FIG. 1, the inspection apparatus 10 includes an optical column 11 in which an electron gun 21 as an emission source of an electron beam EB is installed, a sample chamber 12 in which a wafer W as a substrate is to be arranged, and a control unit 70 that controls each unit of the inspection apparatus 10.

The optical column 11 has a cylindrical shape including a closed upper end portion and a lower end portion opened to allow an electron beam or the like to pass therethrough. The sample chamber 12 is configured to be able to house the wafer W. The optical column 11 and the sample chamber 12 are combined in an airtightly sealed state. The inside of the optical column 11 and the inside of the sample chamber 12 are configured such that they can be held at a reduced pressure by a non-illustrated pump or the like.

In the following description, a light (electron) path along the long axis direction of the optical column 11 is defined as an optical axis of the optical column 11. The optical column 11 is installed to stand upright with respect to the sample chamber 12, and the longitudinal direction and the optical axis of the optical column 11 are approximately perpendicular to the wafer W in the sample chamber 12.

In the optical column 11, the electron gun 21, focusing lenses 31a and 31b, coils 41a, 41b, 42a, 42b, 43a, 43b, 44a, and 44b, an objective lens 32, and a detector 51 are installed in this order from the vicinity of the upper end.

The electron gun 21 emits the electron beam EB downward in the optical column 11. The electron beam EB emitted from the electron gun 21 travels, for example, along the long axis direction of the optical column 11.

The focusing lenses 31a and 31b are electromagnetic coils wound concentrically around the optical axis of the optical column 11, and focus an electron beam EB by a magnetic field.

The coils 41a, 41b, 42a, 42b, 43a, 43b, 44a, and 44b are electromagnetic coils, every two of which make a pair to deflect the electron beam EB or correct astigmatism, and are arranged symmetrically with respect to the optical axis of the optical column 11.

The coils 41a and 41b are electromagnetic coils to deflect the electron beam EB in order to move the position on the wafer W.

The coils 42a and 42b are electromagnetic coils for astigmatism correction that correct astigmatism. If there is astigmatism, vertical and horizontal focuses cannot be adjusted at the same time.

The coils 43a and 43b and the coils 44a and 44b are electromagnetic coils for beam tilt that adjust the incident angle of the electron beam EB to the wafer W. The coils 43a and 43b bend the electron beam EB so as to deviate from the optical axis, and the coils 44a and 44b bend the electron beam EB so as to return to the side of the optical axis. Thereby, the electron beam EB is incident on the wafer W at an angle of, for example, 10° or less with respect to the optical axis.

Here, the incident angle of the electron beam EB with respect to the wafer W is an angle at which the traveling direction of the electron beam EB and a virtual line perpendicular to the wafer W intersect. Therefore, in the above configuration, the electron beam EB is incident on the wafer W at an incident angle of 10° or less.

When the coils 43a, 43b, 44a, and 44b are not used, the electron beam EB is made incident on the wafer W at an angle substantially perpendicular to the wafer W, that is, at an incident angle of approximately 0°, so as to travel along the optical axis.

The objective lens 32 is an electromagnetic coil wound concentrically around the optical axis of the optical column 11, and focuses the electrons emitted toward the wafer W by a magnetic field.

The detector 51 detects the secondary electron generated from the wafer W on which the electron beam EB has been incident.

A wafer stage 61 on which the wafer W is to be mounted is installed in the sample chamber 12. An actuator 62 is attached to the wafer stage 61, so that it is configured that the wafer stage 61 can be driven back and forth and left and right. By driving the wafer stage 61 back and forth and left and right, a predetermined point on the wafer W can be irradiated with the electron beam EB, where the electron beam EB can be made incident on the wafer W.

The control unit 70 is configured as a computer including a central processing unit (CPU), a random access memory (RAM), a storage device, an I/O port, and the like. The RAM, storage device, I/O port, and the like are configured to be able to exchange data with the CPU via an internal bus. An input/output device such as a television monitor or a keyboard may be connected to the control unit 70.

The storage device includes, for example, a flash memory, a hard disk drive (HDD), or the like. In the storage device, a control program, etc., for controlling the operation of the inspection apparatus 10 are stored in a readable manner.

The I/O port is connected to the electron gun 21, the focusing lenses 31a and 31b, the coils 41a, 41b, 42a, 42b, 43a, 43b, 44a, and 44b, the objective lens 32, the detector 51, and the actuator 62 of the wafer stage 61, etc.

The CPU reads the control program from the storage device, and controls the electron gun 21, the focusing lenses 31a and 31b, the coils 41a, 41b, 42a, 42b, 43a, 43b, 44a, and 44b, the objective lens 32, the detector 51, and the actuator 62 of the wafer stage 61, etc., so as to follow the contents of the read control program.

When the control program is read and executed by the CPU, the control unit 70 includes functional units such as, for example, an electron emitting unit 70a, a beam focusing unit 70b, a beam deflecting unit 70c, an astigmatism correcting unit 70d, a beam tilting unit 70e, a focus correcting unit 70f, a signal detecting unit 70g, a data analysis unit 70h, and a stage drive unit 70i.

The electron emitting unit 70a controls the electron gun 21 so as to emit the electron beam EB on the wafer W.

The beam focusing unit 70b controls the focusing lenses 31a and 31b so as to focus the electron beam EB.

The beam deflecting unit 70c controls the coils 41a and 41b so as to deflect the electron beam EB and move the position on the wafer W.

The astigmatism correcting unit 70d controls the coils 42a and 42b so as to correct astigmatism.

The beam tilting unit 70e controls the coils 43a, 43b, 44a, and 44b so as to tilt the incident angle of the electron beam EB on the wafer W.

The focus correcting unit 70f controls the objective lens 32 so as to adjust the focus of the objective lens 32.

The signal detecting unit 70g controls the detector 51 so as to detect a signal by the secondary electron generated from the wafer W.

The data analysis unit 70h analyzes data based on the secondary electron signal detected by the detector 51. For example, a predetermined pattern is formed on the wafer W. The data analysis unit 70h determines the state of the pattern based on the secondary electron signal.

The stage drive unit 70i controls the actuator 62 so as to drive the wafer stage 61.

In the inspection apparatus 10 configured as described above, for example, a voltage contrast (VC) inspection using a potential contrast is performed on the wafer W. The VC inspection is performed by, for example, a two-stage process using a phenomenon in which secondary electrons are released from the wafer W when the wafer W is irradiated with the electron beam EB.

As a first stage process, a process called pre-charging is performed, in which the surface of the wafer W is mainly positively charged by making the electron beam EB incident on the wafer W. At this time, the incident energy (Landing Energy) of the electron beam EB is set, for example, to 1 keV or less, and conditions are adjusted such that the number of the secondary electrons released from the wafer W is larger than the number of the electrons with which the wafer W is irradiated. Hereinafter, the first stage process of the VC inspection may be referred to as a pre-charging process.

As a second stage process, a process is performed, in which the electron beam EB is further made incident on the positively charged wafer W and a potential contrast, due to a difference in the amount of the secondary electrons released from the wafer W, is analyzed. At this time, the incident energy of the electron beam EB is set, for example, to more than 1 keV. Hereinafter, the second stage process of the VC inspection may be referred to as a secondary electron detection process.

(Function Example of Inspection Apparatus)

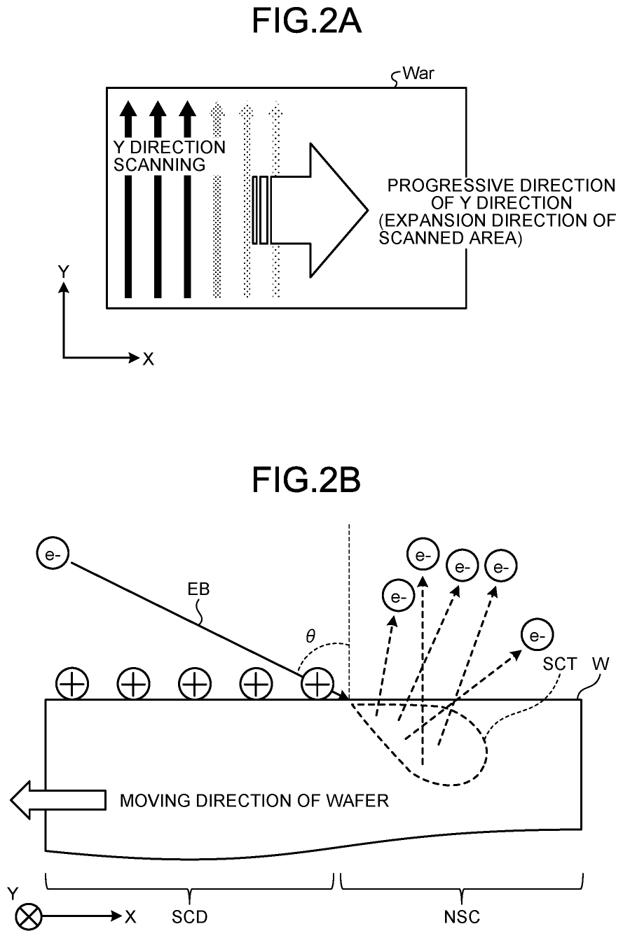

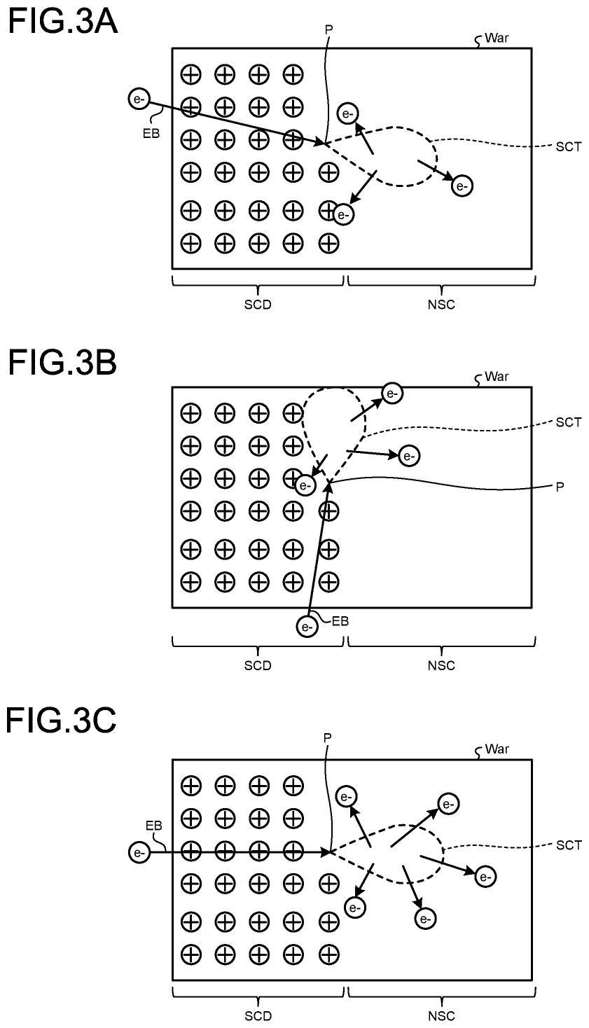

Next, detailed functions of the inspection apparatus 10 configured as described above will be described with reference to FIGS. 2A to 3C. FIGS. 2A to 3C are schematic diagrams each illustrating a state of the pre-charging process in the inspection apparatus 10 according to the first embodiment.

In the pre-charging process for positively charging the wafer W, it is desirable that, for example, the entire surface of the wafer W is positively charged in a short time. Therefore, scanning with the electron beam EB is performed by a scanning method called swath scanning described below. In the following description, a beam position is moved by the deflection with the coils 41a and 41b, and at the same time the position of the wafer W mounted on the wafer stage 61 is moved with respect to the electron gun 21 with the wafer stage 61 driven, based on the above configuration example of the inspection apparatus 10, whereby the incident position of the electron beam EB on the wafer W is moved.

FIG. 2A is a plan diagram of a predetermined area War of the wafer W. In the swath scanning, the wafer W is moved in an opposite X direction while the electron beam EB is being moved in a Y direction by beam deflection, whereby the incident point of the electron beam EB on the wafer W is also moved in the X direction while it is being moved in the Y direction, as illustrated in FIG. 2A. Thereby, the predetermined area War of the wafer W can be positively charged by scanning with the electron beam EB in a short time.

More specifically, scanning in the Y direction is repeated by shifting the start point of the electron beam EB in the X direction every time the electron beam EB is caused to scan once in the Y direction from the start point to the end point. That is, in the swath scanning, the electron beam EB is caused to scan in the direction approximately perpendicular to the moving direction of the wafer stage 61, while the wafer stage 61 is continuously being moved, for example, at a constant speed.

Hereinafter, the scanning in the Y direction, in which the scanning between the start point and the end point is repeated, may be referred to as Y direction scanning, and its scanning and the movement in the X direction may be collectively referred to as swath scanning. In addition, an area where the swath scanning is completed may be referred to as a scanned area, and an area where the swath scanning is to be performed as an unscanned area. In addition, the X direction in the swath scanning may be referred to as a progressive direction of the Y direction scanning (swath scanning) or as an expansion direction of the scanned area.

In such swath scanning, the electron beam EB is emitted from an oblique direction so as to have a predetermined incident angle with respect to the wafer W.

FIG. 2B is an enlarged cross-sectional diagram of the wafer W. In the pre-charging process, the incident direction of the electron beam EB toward the wafer W has a vector component in the direction from a scanned area SCD that has already been scanned with the electron beam EB to an unscanned area NSC, as illustrated in FIG. 2B. That is, an incident angle θ of the electron beam EB to the wafer W is tilted toward the scanned area SCD. The larger the incident angle θ of the electron beam EB with respect to the wafer W, the better.

It is preferable that the above vector component is a vector component in the X direction perpendicular to the Y direction scanning, that is, a vector component in the progressive direction of the swath scanning. At this time, the incident direction of the electron beam EB toward the wafer W is expressed by a vector component in the direction perpendicular to the surface of the wafer W and a vector component in the progressive direction of the above swath scanning.

When the electron beam EB is made incident on the wafer W, a teardrop-shaped scattering area SCT is formed in the traveling direction of the electron beam EB in the wafer W. In the scattering area SCT, secondary electrons are generated by electron scattering. Some of the generated secondary electrons are released from the surface of the wafer W. When a secondary electron release efficiency σ exceeds 1, the surface of the wafer W is positively charged. Therefore, as the secondary electron release efficiency σ is higher and the amount of the secondary electrons released from the surface of the wafer W is larger, the positive charge of the surface of the wafer W is promoted.

As described above, the electron beam EB is incident obliquely from the scanned area SCD side toward the unscanned area NSC. The scattering area SCT is formed in the vicinity of the surface of the wafer W in the unscanned area NSC. For this reason, secondary electrons are easily released, which leads to an increase in the number of secondary electrons released from the surface of the wafer W. Therefore, the secondary electron release efficiency σ is improved, and the positive charge of the wafer W in the unscanned area NSC is promoted.

At this time, the secondary electrons are released from positions slightly shifted from the incident point of the electron beam EB on the wafer W, unlike the case where the electron beam EB is made incident perpendicularly to the wafer W. This is because the scattering area SCT generated by the incidence of the electron beam EB spreads, from the incident point, in a teardrop shape near the surface of the wafer W. This state is illustrated in FIGS. 3A to 3C.

Since the incident direction of the electron beam EB toward the wafer W has a vector component in the direction from the scanned area SCD to the unscanned area NSC, the scattering area SCT spreads mainly toward the unscanned area NSC of the wafer W, as illustrated in FIGS. 3A to 3C. The generated secondary electrons are released from positions shifted from an incident point P of the electron beam EB.

Also, since the incident direction of the electron beam EB toward the wafer W has a vector component in the progressive direction of the swath scanning, the scattering area SCT more surely spreads toward the unscanned area NSC of the wafer W, without overlapping the scanned area SCD, as illustrated in FIG. 3C of FIGS. 3A to 3C.

A positive charge amount on the surface of the wafer W may be different for each predetermined area of the wafer W depending on the state of the pattern of the wafer W. When the electron beam EB is further made incident on the wafer W having a different positive charge amount for each area, secondary electrons of the secondary electrons generated in the wafer W, corresponding to the positive charge amount, are redistributed (neutralized) by the positive charge. Therefore, it is possible to know the state of the pattern of the wafer W based on the release amount of secondary electrons that have escaped the redistribution. A difference in the release amount of secondary electrons is observed by a potential contrast, that is, by a difference in brightness on the surface of the wafer W.

(Pattern Configuration Example)

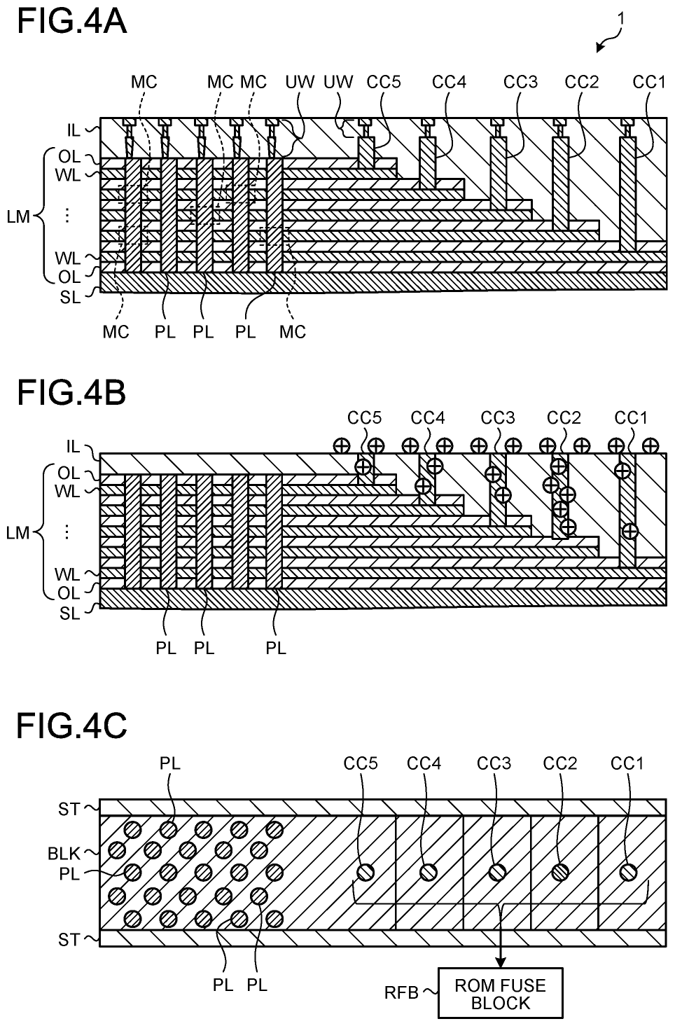

Next, a pattern during the manufacture of a three-dimensional non-volatile memory 1 as a semiconductor memory device, as an example of the pattern of the wafer, and the VC inspection for the pattern will be described with reference to FIGS. 4A to 4C. The VC inspection is performed by using, for example, the above inspection apparatus 10.

FIGS. 4A to 4C are schematic diagrams illustrating a pattern of the wafer and a state of the VC inspection for the pattern according to the first embodiment. FIG. 4A is a cross-sectional diagram of the three-dimensional non-volatile memory 1, FIG. 4B is a cross-sectional diagram of the three-dimensional non-volatile memory that is undergoing the VC inspection during the manufacture, and FIG. 4C is a plan diagram of the three-dimensional non-volatile memory that is undergoing the VC inspection during the manufacture. In FIG. 4C, however, an interlayer insulating layer IL is omitted.

As illustrated in FIG. 4A, the three-dimensional non-volatile memory 1 includes a source line SL and a stacked body LM arranged on the source line SL. The source line SL and the stacked body LM are arranged above the non-illustrated wafer.

The stacked body LM has a configuration in which word lines WL as a plurality of conductive layers are stacked via insulating layers OL. A plurality of pillars PL each having a non-illustrated memory layer are penetrated through the stacked body LM. A plurality of memory cells MC are formed along the height direction of the pillar PL at portions of the pillar PL where the pillar PL intersects the word lines WL.

The end portion of the stacked body LM is formed in a stepped shape, and individual word lines WL are led out by contacts CC1 to CC5. That is, the contacts CC1 to CC5 are arranged in the respective steps of the stepped structure, and the respective contacts are connected to the word lines WL ranging from the lowermost one to the uppermost one.

The upper sides of the pillars PL and the upper side of the stepped structure including the contacts CC1 to CC5 are covered with the interlayer insulating layer IL. The pillar PL is connected to an upper layer wiring UW including a contact, a bit line, etc., in the interlayer insulating layer IL. Each of the upper ends of the contacts CC1 to CC5 is connected to an upper layer wiring UW including a contact, a wiring, etc., in the interlayer insulating layer IL.

The VC inspection for determining whether the contacts CC1 to CC5 are good or bad is performed on the three-dimensional non-volatile memory during the manufacture when, for example, the contacts CC1 to CC5 have been formed, as illustrated in FIG. 4B. At this time, the contacts CC1 to CC5 that are in the vicinity of the surface of the interlayer insulating layer IL, the surface being the surface of the wafer, and that are exposed on the surface of the surface of the interlayer insulating layer IL are positively charged by the pre-charging process in the VC inspection.

Each of the contacts CC1 to CC5 is connected to the underlying word line WL and has an increased electrical capacity. That is, the contact normally connected to the underlying word line WL is hard to be positively charged. For this reason, the contact connected to the underlying word line WL looks bright with a large release amount of secondary electrons by the process of detecting the secondary electrons released from the wafer.

Here, in the example of FIGS. 4B and 4C, the contact CC2 does not reach the word line WL to be connected and is open. Therefore, the contact CC2 does not have the capacity that should be originally held, and looks dark because it is more positively charged than the normal contact CC2.

Thus, according to the VC inspection using the inspection apparatus 10, it is possible to determine whether or not an open failure occurs in the contacts CC1 to CC5, for example, without observing the cross section of the wafer.

Whether the contacts CC1 to CC5 are good or bad is determined for each block BLK that is an area partitioned by a configuration called, for example, a groove-shaped slit ST. The block BLK in which an open failure has occurred is managed as, for example, an unusable bad block in the completed three-dimensional non-volatile memory 1. The three-dimensional non-volatile memory 1 includes, for example, a ROM fuse block RFB as a registration destination of bad block information.

The ROM fuse block RFB is an aggregate of fuse elements on each of which information can be electrically written once, and is provided in the three-dimensional non-volatile memory 1 as a management area for the plurality of the memory cells MC. The ROM fuse block RFB stores various information on the three-dimensional non-volatile memory 1, such as redundancy data on the memory cells MC and bad block information. These information are read out when the three-dimensional non-volatile memory 1 is turned on to be used for controlling various operations of the memory cells MC.

(VC Inspection Method)

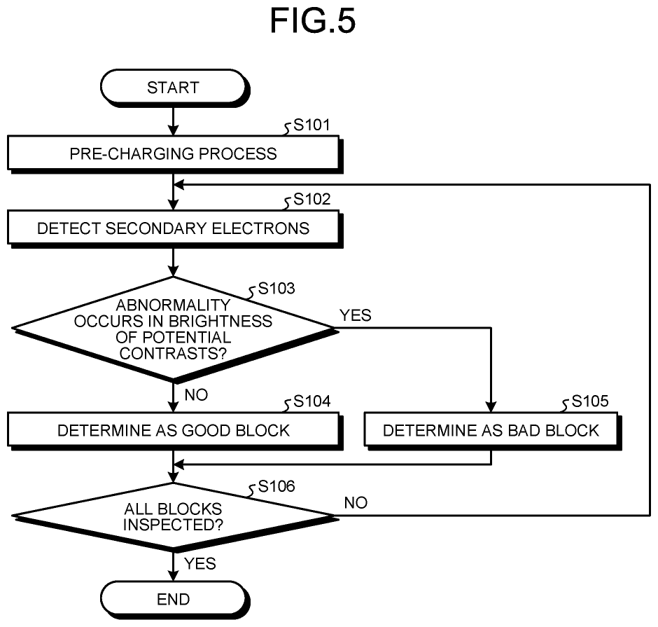

Next, an example of a VC inspection method for the above three-dimensional non-volatile memory will be described with reference to FIG. 5. FIG. 5 is a flowchart illustrating one example of a procedure of a VC inspection method according to the first embodiment.

As illustrated in FIG. 5, the pre-charging process is performed by irradiating the contacts CC1 to CC5 in a predetermined block BLK with the electron beam EB from the electron gun 21 in the optical column 11 (step S101).

In the pre-charging process, the beam deflecting unit 70c controls the coils 41a and 41b, and at the same time the stage drive unit 70i of the control unit 70 controls the actuator 62 of the wafer stage 61 so as to drive the wafer stage 61, whereby a wafer is controlled to be subjected to swath scanning with the electron beam EB. At this time, the electron beam EB is controlled to be obliquely incident on the wafer by operating the coils 43a, 43b, 44a, and 44b.

More specifically, the electron emitting unit 70a of the control unit 70 controls the electron gun 21 so as to emit the electron beam EB. The beam focusing unit 70b controls the focusing lenses 31a and 31b so as to focus the electron beam EB. The beam deflecting unit 70c controls the coils 41a and 41b so as to move the incident position of the electron beam EB with respect to the wafer. The astigmatism correcting unit 70d controls the coils 42a and 42b so as to correct the astigmatism of the electron beam EB. The beam tilting unit 70e controls the coils 43a, 43b, 44a, and 44b so as to make the electron beam EB obliquely incident on the wafer.

The above pre-charging process is performed, for example, on all of the blocks BLK arranged on the wafer.

The contacts CC1 to CC5 in a predetermined block BLK, of the blocks BLK subjected to the pre-charging process, are further irradiated with the electron beam EB, whereby a difference in the release amount of secondary electrons in the contacts CC1 to CC5 is detected (step S102). At this time, the electron beam EB is controlled to be approximately perpendicularly incident on the wafer by stopping the coils 43a, 43b, 44a, and 44b.

More specifically, the electron emitting unit 70a, the beam focusing unit 70b, the beam deflecting unit 70c, and the astigmatism correcting unit 70d control each unit. The beam tilting unit 70e stops the operations of the coils 43a, 43b, 44a, and 44b.

Also, while the focus correcting unit 70f of the control unit 70 is adjusting the focus of the objective lens 32, the detector 51 detects secondary electrons, whereby a detection signal is received by the signal detecting unit 70g.

The data analysis unit 70h of the control unit 70 analyzes the secondary electron signal transmitted to the signal detecting unit 70g, and determines whether or not an abnormality occurs in the brightness of the potential contrasts of the contacts CC1 to CC5 (step S103).

If no abnormality occurs in the brightness of the potential contrasts (step S103: No), the data analysis unit 70h assumes that an open failure, due to the contacts CC1 to CC5 not reaching the word lines WL, does not occur, and determines the block BLK to be inspected as a good block (step S104).

If an abnormality occurs in the brightness of the potential contrasts (step S103: Yes), the data analysis unit 70h assumes that an open failure, due to any one of the contacts CC1 to CC5 not reaching the word line WL, occurs, and determines the block BLK to be inspected as a bad block (step S105).

The control unit 70 determines whether or not the VC inspection has been performed on all of the blocks BLK (step S106). If there is a block BLK on which the VC inspection has not been performed (step S106: No), the control unit 70 causes the processing from the step S102 to be repeated. When the VC inspection has been performed on all of the blocks BLK (step S106: Yes), the control unit 70 ends the VC inspection.

With the above, the VC inspection according to the first embodiment is completed. The results of the above VC inspection are stored, for example, in the ROM fuse block of the completed three-dimensional non-volatile memory 1.

In the above description, the pre-charging process is collectively performed on all of the blocks BLK on the wafer W; however, the present invention is not limited thereto. The pre-charging process may be collectively performed on some of the blocks BLK on the wafer. Alternatively, the secondary electron detection process may be performed every time one block BLK is pre-charged or every time a chip area, an area for cutting out the three-dimensional non-volatile memory 1, is pre-charged.

As the number of stacked layers such as the conductive layers of the three-dimensional non-volatile memory described above increases, the capacity in the depth direction of a configuration to be positively charged increases, and the pre-charging process of the VC inspection takes a longer time. Even if it is intended to optimize the incident energy of electrons, the release amount of secondary electrons is generally determined by a material. Also, even if it is intended to increase the number of electrons to be emitted, there is a restriction due to the design of an inspection apparatus.

According to the VC inspection method of the first embodiment, the electron beam EB is made incident on the wafer W while the positions of the electron gun 21 and the wafer W are being moved relatively, in the pre-charging process. More specifically, the scanning with the electron beam EB in the pre-charging process is implemented by swath scanning in which scanning in the Y direction is repeated by shifting the start point of the electron beam EB in the X direction every time the electron beam EB is caused to scan in the Y direction from the start point to the end point. Thereby, a wide area of the wafer W can be quickly positively charged.

According to the VC inspection method of the first embodiment, the incident angle of the electron beam EB with respect to the wafer W in the pre-charging process is made different from the incident angle of the electron beam EB with respect to the wafer W in the secondary electron detection process. More specifically, the incident direction of the electron beam EB is made oblique to the wafer W in the pre-charging process, while the incident direction of the electron beam EB is made perpendicular to the wafer W in the secondary electron detection process. Thereby, in the pre-charging process, secondary electrons can be generated by scattering electrons near the surface of the wafer W, and an amount of secondary electrons released from the wafer W can be increased, so that the positive charge can be promoted. Therefore, the time for the pre-charging process can be shortened.

According to the VC inspection method of the first embodiment, in the pre-charging process, the incident direction of the electron beam EB toward the wafer W has a vector component in the direction from the scanned area SCD to the unscanned area NSC. Preferably, the direction from the scanned area SCD to the unscanned area NSC is the progressive direction of the swath scanning, opposite to the moving direction of the wafer W and the wafer stage 61.

If the scattering area is formed in the scanned area of the wafer, for example, by making the incident direction of the electron beam opposite to the above, redistribution with the positive charge of the surface of the wafer occurs due to the generated secondary electrons. In some cases, the electron beam scattered in the scattering area is released itself as backscattered electrons, which are redistributed with the positive charge of the surface of the wafer. Thereby, the positive charge of the surface of the wafer is inhibited.

According to the VC inspection method of the first embodiment, with the above configuration, the scattering area SCT can be more surely formed in the unscanned area NSC of the wafer W, whereby the inhibition for the positive charge of the surface of the wafer W, due to the redistribution with secondary electrons, can be suppressed.

### Second Embodiment

Hereinafter, a second embodiment will be described in detail with reference to the drawings. An inspection apparatus 20 of the second embodiment is different from the above first embodiment in that a pre-charging process and a secondary electron detection process are performed by using different optical columns.

(Configuration Example of Inspection Apparatus)

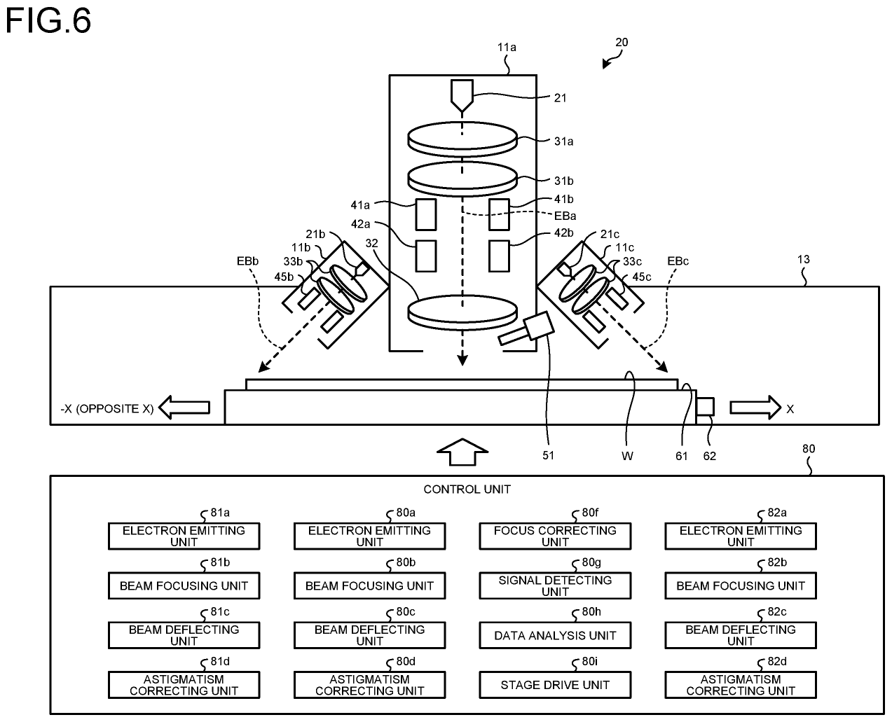

FIG. 6 is a schematic diagram illustrating a configuration example of the inspection apparatus 20 according to the second embodiment. As illustrated in FIG. 6, the inspection apparatus 20 includes a plurality of optical columns 11a to 11c, a sample chamber 13 in which a wafer W as a substrate is to be arranged, and a control unit 80 that controls each unit of the inspection apparatus 20.

Each of the optical columns 11a to 11c has a cylindrical shape including a closed upper end portion and a lower end portion opened to allow an electron beam or the like to pass therethrough. The sample chamber 13 is configured to be able to house the wafer W. The optical columns 11a to 11c and the sample chamber 13 are combined in an airtightly sealed state. The insides of the optical columns 11a to 11c and the inside of the sample chamber 13 are configured such that they can be held at a reduced pressure by a non-illustrated pump or the like.

The optical column 11a is configured in the same manner as the optical column 11 of the inspection apparatus 10 of the above first embodiment, except that the coils 43a, 43b, 44a, and 44b are not included. The optical axis of the optical column 11a is approximately perpendicular to the wafer W in the sample chamber 13, and the optical column 11a is used, for example, in the process of detecting secondary electrons released from the wafer W.

In the optical column 11b, an electron gun 21b, a focusing lens 33b, and a coil 45b are installed in this order from the vicinity of the upper end portion. In the optical column 11c, an electron gun 21c, a focusing lens 33c, and a coil 45c are installed in this order from the vicinity of the upper end portion. The coils 45b and 45c are electromagnetic coils, for example, for beam deflection, astigmatism correction, etc.

The optical columns 11b and 11c are arranged on both sides of the optical column 11a in a state tilted at a predetermined angle. The upper end portions of the optical columns 11b and 11c are tilted toward the optical column 11a, and the lower end portions of the optical columns 11b and 11c are tilted away from the optical column 11a. That is, the optical columns 11b and 11c are tilted in opposite directions to each other.

Thereby, the optical axes of the optical columns 11b and 11c are tilted with respect to the wafer W in the sample chamber 13, respectively. Preferably, electron beams EBb and EBc emitted from the optical columns 11b and 11c are incident on the wafer W at an incident angle exceeding, for example, 10°. These optical columns 11b and 11c are used, for example, in the process of positively charging the surface of the wafer W.

More specifically, the optical column 11b is used, for example, when the wafer W is moved in the X direction in swath scanning. The optical column 11c is used, for example, when the wafer W is moved in the −X direction (opposite X direction) in the swath scanning. Also, for example, the optical column 11c may be used when the half surface on the X direction side of the wafer W is pre-charged, and the optical column 11b may be used when the half surface on the −X direction side of the wafer W is pre-charged.

By adopting the arrangement as described above, the optical axes of the optical columns 11a to 11c do not intersect each other in the traveling directions of electron beams EBa to EBc emitted by the respective electron guns 21, 21b, and 21c. That is, the electron beams EBa to EBc do not intersect each other.

The optical columns 11b and 11c and their internal respective units can be configured to be smaller than the optical column 11a and its internal respective units. This is because the optical columns 11b and 11c that perform the pre-charging process are not required to be more accurate than the optical column 11a that performs the secondary electron detection process. That is, the optical columns 11b and 11c that perform the pre-charging process are smaller in size than the optical column 11a that performs the secondary electron detection process.

In the sample chamber 13, a wafer stage 61 to which an actuator 62 is attached is installed.

The control unit 80 is configured as a computer including a central processing unit (CPU), a random access memory (RAM), a storage device, an I/O port, etc., like the control unit 70 of the above first embodiment.

The I/O port is connected to each unit in the optical column 11a and to each unit in the sample chamber 13. The I/O port is also connected to the electron gun 21b, the focusing lens 33b, and the coil 45b in the optical column lib, the electron gun 21c, the focusing lens 33c, and the coil 45c in the optical column 11c, and the like.

The CPU controls each unit in the optical column 11a and each unit in the sample chamber 13 so as to follow the contents of the control program read from the storage device. The CPU also controls the electron gun 21b, the focusing lens 33b, and the coil 45b in the optical column 11b, the electron gun 21c, the focusing lens 33c, and the coil 45c in the optical column 11c, and the like.

When the control program is read and executed by the CPU, the control unit 80 includes functional units such as, for example, electron emitting units 80a to 82a, beam focusing units 80b to 82b, beam deflecting units 80c to 82c, astigmatism correcting units 80d to 82d, a focus correcting unit 80f, a signal detecting unit 80g, a data analysis unit 80h, and a stage drive unit 80i.

The electron emitting unit 80a, the beam focusing unit 80b, the beam deflecting unit 80c, the astigmatism correcting unit 80d, the focus correcting unit 80f, the signal detecting unit 80g, the data analysis unit 80h, and the stage drive unit 80i have the similar functions to the electron emitting unit 70a, the beam focusing unit 70b, the beam deflecting unit 70c, the astigmatism correcting unit 70d, the focus correcting unit 70f, the signal detecting unit 70g, the data analysis unit 70h, and the stage drive unit 70i of the above first embodiment, respectively.

The electron emitting unit 81a controls the electron gun 21b so as to emit the electron beam EBb on the wafer W. The electron emitting unit 82a controls the electron gun 21c so as to emit the electron beam EBc on the wafer W.

The beam focusing unit 81b controls the focusing lens 33b so as to focus the electron beam EBb. The beam focusing unit 82b controls the focusing lens 33c so as to focus the electron beam EBc.

The beam deflecting unit 81c controls the coil 45b so as to move the beam position of the electron beam EBb on the wafer W. The beam deflecting unit 82c controls the coil 45c so as to move the beam position of the electron beam EBc on the wafer W.

The astigmatism correcting unit 81d controls the coil 45b so as to correct the astigmatism of the electron beam EBb. The astigmatism correcting unit 82d controls the coil 45c so as to correct the astigmatism of the electron beam EBc.

Herein, the number of the optical columns 11b and 11c that perform the pre-charging process is not limited to two. The number of optical columns that perform the pre-charging process may be one, or three or more. The number of optical columns that perform the pre-charging process may be set, for example, to four, which may be arranged at equal intervals around the optical column that performs the secondary electron detection process.

(Function Example of Inspection Apparatus)

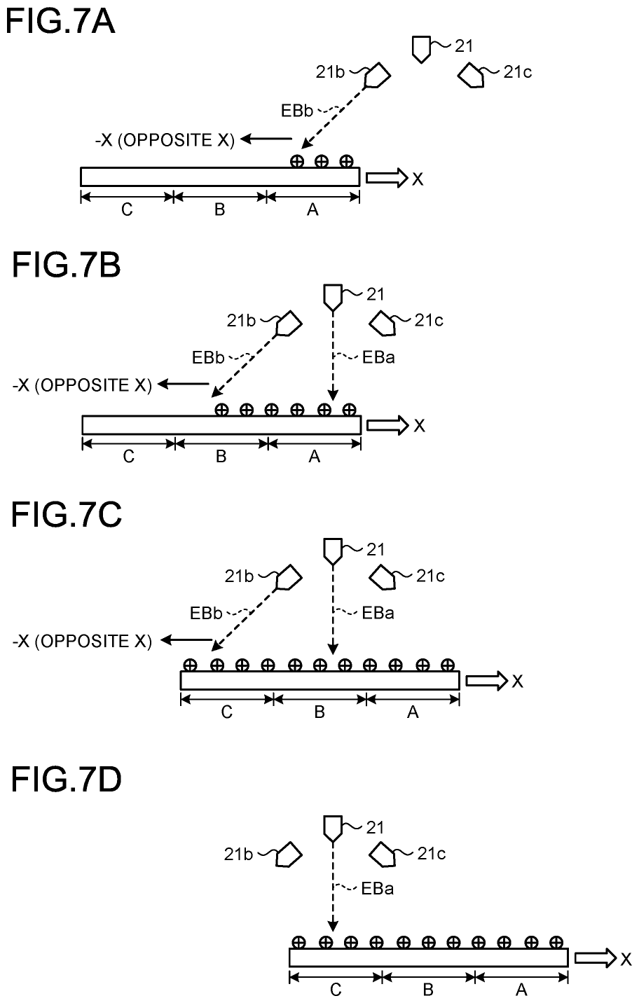

Next, detailed functions of the inspection apparatus 20 configured as described above will be described with reference to FIGS. 7A to 7D. FIGS. 7A to 7D are schematic diagrams each illustrating a state of the VC inspection in the inspection apparatus 20 according to the second embodiment.

In the example of FIGS. 7A to 7D, the wafer W is irradiated with the electron beam EBb from the electron gun 21b of the optical column 11b while the wafer stage 61 is being moved in the X direction, whereby the surface of the wafer W is positively charged. At this time, the wafer W is divided into, for example, a plurality of areas A to C, and the pre-charging process and the secondary electron detection process are performed in parallel on the different areas A to C of the wafer W.

As illustrated in FIG. 7A, the vicinity of the center of the wafer W is set as a second area B, an area on the X direction side with respect to the second area B as a first area A, and an area on the −X direction side with respect to the second area B as a third area C.

The wafer stage 61 is moved such that the electron beam EBb from the electron gun 21b is incident on the end portion on the X direction side of the wafer W, that is, on the end portion on the first area A side. Then, while the wafer stage 61 is being moved from the position in the X direction, the pre-charging process is performed on the first area A of the wafer W.

That is, while the wafer W is being irradiated with the electron beam EBb, the swath scanning with the electron beam EBb is gradually progressed in the −X direction (opposite X direction). In the example of FIGS. 7A to 7D, the −X direction becomes the progression direction of the swath scanning, and a scanned area of the surface of the wafer W expands within the first area A from the end portion of the wafer W toward the −X direction, as described above.

As illustrated in FIG. 7B, when the wafer stage 61 is continuously moved in the X direction, the first area A of the wafer W comes under the electron gun 21. Then, the swath scanning is performed by emitting from the electron gun 21 the electron beam EBa on the wafer W, and the secondary electron detection process is performed on the first area A.

On the other hand, the central portion of the wafer W, that is, the second area B has moved to the emission position of the electron beam EBb from the electron gun 21b. Then, the pre-charging process is performed on the second area B by emitting from the electron gun 21b the electron beam EBb on the wafer W.

As described above, the secondary electron detection process for the first area A and the pre-charging process for the second area B are performed in parallel, while the wafer stage 61 is being moved in the X direction.

As illustrated in FIG. 7C, when the wafer stage 61 is continuously moved in the X direction, the second area B of the wafer W moves to the irradiation position by the electron beam EBa from the electron gun 21, and the third area C of the wafer W moves to the irradiation position by the electron beam EBb from the electron gun 21b. Then, the secondary electron detection process for the second area B and the pre-charging process for the third area C are performed in parallel, while the wafer stage 61 is being moved in the X direction.

When the irradiation of the third area C of the wafer W with the electron beam EBb is completed, the pre-charging process for the wafer W is completed.

As illustrated in FIG. 7D, the third area C of the wafer W is moved to the irradiation position by the electron beam EBa from the electron gun 21 by continuing the movement of the wafer stage 61 in the X direction, so that the secondary electron detection process for the third area C is performed.

As described above, the inspection apparatus 20 has the function of performing in parallel the pre-charging process and the secondary electron detection process for the different areas A to C of the wafer W.

(VC Inspection Method)

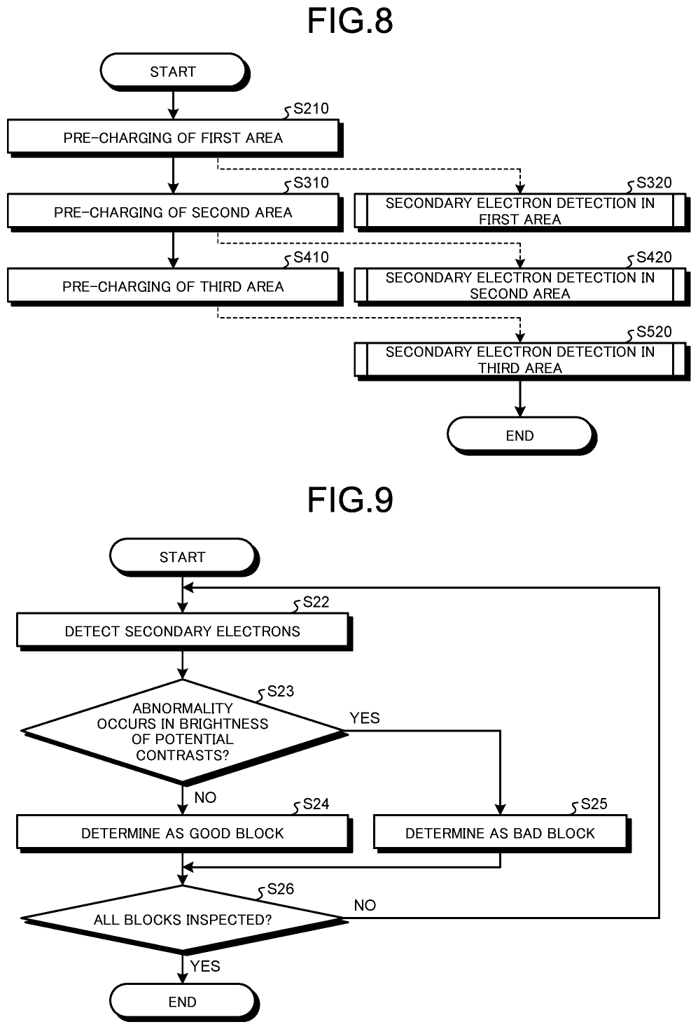

Next, an example of a VC inspection method using the inspection apparatus 20 of the second embodiment will be described with reference to FIGS. 8 and 9. FIGS. 8 and 9 are flowcharts each illustrating an example of the procedure of a VC inspection method by the inspection apparatus 20 according to the second embodiment. In the examples of FIGS. 8 and 9, it is also assumed that the pre-charging process is performed by using the optical column lib. It is also assumed that the VC inspection is performed on the contacts CC1 to CC5 of the three-dimensional non-volatile memory of the above first embodiment.

As illustrated in FIG. 8, the first area A of the wafer W is irradiated with the electron beam EBb from the electron gun 21b while the wafer stage 61 is being moved by the stage drive unit 80i of the control unit 80, so that the pre-charging process for the first area A is performed (step S210).

More specifically, the electron emitting unit 81a of the control unit 80 controls the electron gun 21b so as to emit the electron beam EBb. The beam focusing unit 81b controls the focusing lens 33b so as to focus the electron beam EBb. The beam deflecting unit 81c controls the coil 45b so as to move the position of the electron beam EBb with respect to the wafer W. The astigmatism correcting unit 81d controls the coil 45b so as to correct the astigmatism of the electron beam EBb.

While the wafer stage 61 is being moved, the pre-charging process for the second area B of the wafer W is performed (step S310). At this time, the electron emitting unit 81a, the beam focusing unit 81b, the beam deflecting unit 81c, and the astigmatism correcting unit 81d of the control unit 80 control each unit in the optical column lib, similarly to the above.

In parallel with this, the electron beam EBa from the electron gun 21 is emitted on the first area A of the wafer W, whereby the secondary electron detection process for the first area A is performed (step S320). A detailed flow of the secondary electron detection process will be described later.

While the wafer stage 61 is being moved, the pre-charging process for the third area C of the wafer W is performed (step S410). In parallel with this, the secondary electron detection process for the second area B of the wafer W is performed (step S420).

While the wafer stage 61 is being moved, the secondary electron detection process for the third area C of the wafer W is performed (step S520).

With the above, the VC inspection using the inspection apparatus 20 of the second embodiment is completed.

As illustrated in FIG. 9, the secondary electron detection process (steps S22 to S26) using the inspection apparatus 20 of the second embodiment is performed in the same manner as the steps S102 to S106 of FIG. 5 in the above first embodiment.

That is, in the block BLK in a predetermined area on which the pre-charging process has been performed, the electron beam EBa is emitted from the electron gun 21 on the contacts CC1 to CC5, so that differences among the release amounts of secondary electrons in the contacts CC1 to CC5 are detected (step S22). That is, the detector 51 detects potential contrasts as the release amounts of secondary electrons, and the signal detecting unit 80g of the control unit 80 receives these information as signals by the secondary electrons.

The data analysis unit 80h of the control unit 80 analyzes the signals of the secondary electrons transmitted to the signal detecting unit 80g, and determines whether or not an abnormality occurs in the brightness of the potential contrasts generated in the contacts CC1 to CC5 (step S23).

If no abnormality occurs in the brightness of the potential contrasts (step S23: No), the data analysis unit 80h determines the block BLK under the inspection as a good block (step S24).

If an abnormality occurs in the brightness of the potential contrasts (step S23: Yes), the data analysis unit 80h determines the block BLK under the inspection as a bad block (step S25).

The control unit 80 determines whether or not the VC inspection has been performed on all of the blocks BLK (step S26). If there is a block BLK on which the VC inspection has not been performed (step S26: No), the control unit 80 causes the processing from the step S22 to be repeated. When the VC inspection has been performed on all of the blocks BLK (step S26: Yes), the control unit 80 ends the VC inspection.

With the above, the VC inspection using the inspection apparatus 20 of the second embodiment is completed.

The inspection apparatus 20 of the second embodiment also has the same effects as those of the first embodiment.

According to the inspection apparatus 20 of the second embodiment, the optical columns 11b and 11c that perform the pre-charging process are provided separately from the optical column 11a that detects secondary electrons. Thereby, the secondary electron detection process and the pre-charging process can be performed in parallel on one wafer W. Therefore, the time for the VC inspection can be shortened.

According to the inspection apparatus 20 of the second embodiment, the optical columns 11b and 11c are installed in a tilted state with respect to the optical column 11a, and the optical axes of these optical columns 11a to 11c do not intersect each other in the directions in which the electron beams EBa to EBc emitted by the respective electron guns 21, 21b, and 21c travel respectively. Thereby, when the secondary electron detection process and the pre-charging process are performed in parallel, the electron beams EBa to EBc are suppressed from interfering with each other.

According to the inspection apparatus 20 of the second embodiment, the tilt angle of the optical columns 11b and 11c with respect to the optical column 11a is more than 10°. Thereby, the incident angles of the electron beams EBb and EBc with respect to the wafer W can be set to, for example, more than 10°. That is, the incident directions of the electron beams EBb and EBc can be further tilted with respect to the wafer W.

For example, when the secondary electron detection process and the pre-charging process are performed with one optical column 11, as in the above first embodiment, the incident angle of the electron beam EB with respect to the wafer W is, for example, 10° or less. That is, it is difficult to greatly tilt the incident direction of the electron beam EB with respect to the wafer W, due to restrictions such as the size of the optical column 11.

According to the inspection apparatus 20 of the second embodiment, the incident angles of the electron beams EBb and EBc with respect to the wafer W can be increased by increasing the tilt of the optical columns 11b and 11c with respect to the optical column 11a. Thereby, the scattering area SCT can be formed at a position closer to the surface of the wafer W, whereby the release amount of secondary electrons is improved and the amount of positive charge of the surface of the wafer W is increased. Therefore, the time for the pre-charging process can be further shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An inspection method comprising:
positively charging a substrate on which a pattern is formed by irradiating the substrate with a first electron beam;
generating a secondary electron on a surface of the substrate by irradiating the substrate with a second electron beam,
detecting the generated secondary electron; and
inspecting the pattern based on the detected secondary electron, wherein
when the substrate is irradiated with the first electron beam,
the first electron beam is made incident on the substrate at an incident angle different from an incident angle of the second electron beam with respect to the substrate, while positions of an emission source of the first electron beam and the substrate are being moved relatively.

2. The inspection method according to claim 1, wherein
when the substrate is irradiated with the first electron beam,
an incident direction of the first electron beam toward the substrate has a vector component in a direction from a first area that has already been scanned with the first electron beam to a second area that has not been scanned.

3. The inspection method according to claim 1, wherein
when the substrate is irradiated with the first electron beam,
the substrate is scanned with the first electron beam in an opposite direction to a first direction while the substrate is continuously being moved in the first direction, and
an incident direction of the first electron beam toward the substrate has a vector component along the opposite direction.

4. The inspection method according to claim 3, wherein
when the substrate is irradiated with the first electron beam,
the substrate is moved in the first direction while the first electron beam is being moved in a second direction intersecting the first direction by deflecting the first electron beam.

5. The inspection method according to claim 1, wherein
when the substrate is irradiated with the first electron beam,
the incident angle of the first electron beam is made different from the incident angle of the second electron beam by deflecting the first electron beam.

6. The inspection method according to claim 5, wherein
the incident angle of the first electron beam with respect to the substrate is set to 10° or less.

7. The inspection method according to claim 1, wherein
when the substrate is irradiated with the first electron beam,
an optical column that houses the emission source of the first electron beam is arranged with respect to the substrate at an angle different from an angle of an optical column that houses an emission source of the second electron beam.

8. The inspection method according to claim 7, wherein
the incident angle of the first electron beam with respect to the substrate is set to more than 10°.

9. The inspection method according to claim 1, wherein
on the substrate,
a stacked body having a stepped portion in which a plurality of conductive layers are stacked via insulating layers and end portions of the plurality of conductive layers terminate in a stepped shape, and a plurality of contacts that are arranged for each step of the stepped portion and are to be respectively conducted with the conductive layers of the respective steps, are formed,
the plurality of contacts are positively charged by irradiating the substrate with the first electron beam,
potential contrasts are generated in the plurality of contacts by irradiating the substrate with the second electron beam, and
based on the potential contrasts, it is determined whether or not an open failure occurs in at least one of the plurality of contacts.

10. The inspection method according to claim 9, wherein
of the plurality of contacts, a contact in which the open failure occurs is observed at a lower brightness than a contact in which the open failure does not occur.

11. The inspection method according to claim 9, wherein
the secondary electrons from, of the plurality of contacts, a contact in which the open failure occurs are detected at a lower release amount than a contact in which the open failure does not occur.

12. An inspection apparatus comprising:
a first optical column that positively charges a substrate on which a pattern is formed by irradiating the substrate with a first electron beam; and
a second optical column that generates a secondary electron on a surface of the substrate by irradiating the substrate with a second electron beam, the pattern being inspected by detecting the secondary electron, wherein
the first optical column and the second optical column are arranged at different angles with respect to the substrate.

13. The inspection apparatus according to claim 12, wherein
an optical axis of the first optical column and an optical axis of the second optical column do not intersect each other in traveling directions of the electron beams.

14. The inspection apparatus according to claim 12, further comprising:
a stage on which the substrate is mounted; and
a control unit that controls the first and second optical columns and the stage, wherein
when the substrate is irradiated with the first electron beam,
the control unit causes:
the substrate to be scanned with the first electron beam in an opposite direction to a first direction while the stage on which the substrate is mounted is continuously being moved in the first direction; and
the first electron beam to be emitted such that an incident direction of the first electron beam toward the substrate has a vector component along the opposite direction.

15. The inspection apparatus according to claim 14, wherein
when the substrate is irradiated with the first electron beam,
the control unit causes
the stage on which the substrate is mounted to be moved in the first direction while the first electron beam is being moved in a second direction intersecting the first direction by deflecting the first electron beam.

16. The inspection apparatus according to claim 14, wherein
the substrate has
a first area, a second area, and a third area that are lined up along the opposite direction, and
the control unit causes:
while the stage on which the substrate is mounted is being moved in the first direction,
the first area to be scanned with the first electron beam;
next, the second area to be scanned with the first electron beam, and in parallel with this, the first area to be scanned with the second electron beam; and
next, the third area to be scanned with the first electron beam, and in parallel with this, the second area to be scanned with the second electron beam.

17. The inspection apparatus according to claim 12, wherein
a dimension of the first optical column is smaller than a dimension of the second optical column.

18. The inspection apparatus according to claim 12, wherein
the second optical column is arranged such that a longitudinal direction of the second optical column is substantially perpendicular to the substrate.

19. The inspection apparatus according to claim 18, wherein
an optical axis of the first optical column and an optical axis of the second optical column form an angle of more than 10°.

20. The inspection apparatus according to claim 18, wherein
the first optical column has two optical columns arranged to be tilted in opposite directions with respect to the second optical column.
